(19) United States
(12) Patent Application Publication
(10) Pub. No.: US 2019/0003053 A1
(43) Pub. Date: Jan. 3, 2019

(54) CHEMICAL VAPOR PHASE GROWTH APPARATUS

(71) Applicant: National Chiao Tung University, Hsinchu City (TW)

(72) Inventors: Wei-Kuo CHEN, Hsinchu City (TW); Chun-Hung CHENG, Hsinchu City (TW)

(21) Appl. No.: 15/975,421

(22) Filed: May 9, 2018

(30) Foreign Application Priority Data
Jun. 30, 2017 (TW) 106121960

(51) Int. Cl. C23C 16/46

(52) U.S. Cl. CPC C23C 16/463

(57) ABSTRACT

A chemical vapor phase growth apparatus for growing films on substrates comprises of a thermostated lower heating element, including a plurality of carrier disks thereon, wherein each carrier disk further includes a plurality of substrates thereon for film deposition; a plurality of partitions, disposed above the lower heating element to define a plurality of sub-reaction chambers; a plurality of upper heating elements made of a plurality of thermostated upper heating units, disposed over the lower heating element by a gap to form reaction zones in each sub-reaction chamber; a gas inlet installed in each sub-reaction chamber to provide at least one precursor into the sub-reaction chamber; and a gas outlet installed in the chemical vapor phase growth apparatus to exhaust the gases.

### BACKGROUND OF THE INVENTION

### 1. Field of the Invention

The present invention relates to a chemical vapor phase growth apparatus, particularly a chemical vapor phase growth apparatus having a plurality of sub-reaction chambers with upper heating elements and a shared lower heating element, wherein the upper heating element of each sub-reaction chamber including a plurality of thermostated upper heating units is arranged in the upper region of the sub-reaction chamber. The lower heating element is to provide the substrate temperature for film growth and the upper heating element in each sub-reaction chamber together with the lower heating element is to form a 3D (both radial and the vertical directions) temperature profile in each individual sub-reaction chamber.

### 2. Description of the Prior Art

Chemical vapor deposition (CVD) apparatus is commonly used to fabricate different types of materials, such as insulators, conductors and semiconductors. The CVD apparatus has been used to fabricate varieties of consumer electronics, optical devices and industrial functioned elements. At 2017, the annual global market for power-IC industry is about 35 billion, for MEMS industry is about 13 billion, and for optoelectronic industry (including light emitting diodes (LED) and illuminators) is about 21 billion. The major attractions of CVD growth technique are its suitability and versatility for mass production of growing high-quality thin films, which reduces greatly the fabrication cost and hence brings prosperities of industry.

Chemical vapor deposition is a method for film fabrication, wherein precursors are fed into a reaction chamber to chemically react homogeneously in the gas stream and heterogeneously on the growing interface to form a film on the substrate. For CVD film growth, temperature unquestionably is one of the most important growth parameters. To fabricate high-quality film, the substrate temperature in typical CVD is required to meet the demands of efficient thermal cracking of the major source precursors, and at the same time to meet the demand of deposition temperature, which is required to be high enough to overcome the surface chemical reaction barrier. However, too high or too low temperature also impairs the film deposition. Since this will bring about the generation of large quantities of structure, point defects and/or the decomposition of the deposited film. It is obviously that the sole substrate temperature to meet all the demands is not an easy job. Currently, there are several major CVD technologies available for growth of materials, including (1) the cold-wall CVD (CWCVD) system, (2) the hot-wall CVD (HWCVD) system, (3) the thermal gradient CVD (TGCVD) system, and (4) the sub-reaction chambers CVD (SCVD) system.

When a multicomponent compound is to be deposited, different source precursors have to be used. Normally, these precursors exhibit different thermal-cracking temperatures, in which the suitable cracking temperature range may not well overlap with each other and often differ markedly, such as SiH₄ (1150° C.) and GeH₄ (830° C.) for SiGe binary, SiH₄ (1150° C.) and C₃H₈ (900° C.) for SiC binary, and TMGa (˜937° C.) and TMIn (˜500° C.) for InGaN ternary. For these material growths, the CVD reactor equipped with only substrate heater is apparently unable to meet all the cracking demands of the source precursors, not to mention the need for the surface chemical reactions. This inevitably leads to a narrowed growth window and often fails to attain the best film quality for these materials.

The U.S. Pat. No. 3,293,074 disclosed a cold-wall CVD (CWCVD) system in 1966, featuring with one heating element. In this patent, the heating element disposed beneath the substrate (called the lower heating element in the present invention) is the only heat source of the reaction chamber, providing both the necessitated temperature for growing films and the required thermal energy for cracking precursors. In the growth process, the precursors decompose and/or polymerize in the thermal boundary layer. The decomposed species approach the substrate via diffusion, adsorb on the surface, and finally conduct the surface reaction steps to deposit the film on the substrate. Owing to the simplicity of the reactor, this system has been widely used to fabricate varieties of electronic and optoelectronic devices, high-speed devices, metal-oxide-semiconductor field-effect transistors and etc.

The U.S. Pat. No. 4,533,820 in 1985 disclosed an isothermal hot-wall CVD (HWCVD) system. Different from the CWCVD system, the HWCVD system is a type of oven reactor heated by heating devices, such as filaments to surround the reactor. This heating device heats evenly the entire reaction chamber, including the substrate holder (susceptor), and substrates themselves, to provide the desired substrate temperature and cracking temperature for film growth. In this configuration, the reaction chamber and the substrate temperatures are about the same. HWCVD, normally operating at a higher temperature as compared to CWCVD, is particularly suitable for growing high-thermal stability films whose precursors are hard to crack, such as films of SiC, TiC, TiO₂, SiO₂, and SiN, due to primarily the satisfactory pyrolysis of source precursors

The thermal gradient CVD (TGCVD) system is another type of CVD system, disclosed by U.S. Pat. No. 5,759,263 in 1998, which includes a lower heating element disposed at the lower portion of the reaction chamber, a substrate disposed on the lower heating element for film deposition, and an upper heating element disposed at upper portion of the reaction chamber. The temperature difference between the upper heating the lower heating elements generates a vertical temperature gradient in the deposition zone above the substrate. In this type of reactor, the upper and the lower heating elements are normally controlled independently and the temperature of the upper heating element is normally set a value higher than that of the lower heating element, whereby a temperature gradient is generated. Apparently, the use of the high-temperature upper heating element in the chamber raises the temperature of source precursors in the gas phase, which in turn enhances their thermal cracking efficiencies. Thus, the TGCVD is often applied to fabricate films wherein at least one of the main source precursors is hard to decompose.

The U.S. Pat. No. 5,281,274 in 1994 and U.S. Pat. No. 5,730,802 in 1998 disclosed another type of CVD system, a multiple sub-chamber CVD system (MSCVD) assigned here. This reactor is based on the configuration of a cold-wall CVD, with its reaction chamber further being divided into several sub-reaction chambers by use of partitions. The reactor disclosed in this patent is equipped only one heating element, i.e., substrate heating element in the chamber. The substrates are placed on the susceptor heated by substrate heating element. In one operation mode, the cation source, carrier gas, anion source and carrier gas are fed into their respective sub-reaction chambers. The rotating of the susceptor allows each of the substrates capable of entering into different sub-reaction chambers to conduct the layer-by-layer growth mode. When the thickness of each layer is controlled precisely to one atomic layer thickness, this operation mode then becomes a so-called atom-layer growth mode. That is to say, this technology features atom-scale thickness controllability and superior thickness homogeneity, making it particularly appropriate for the preparation of nanometric thin film structures, such as 10 nm class semiconductor films, seed layers, metal interconnections, high-permittivity gate layers, barrier layers and etc. in cutting-edge IC industry.

Nevertheless, the abovementioned CVD systems respectively have different limitations in use. The basic limitations thereof are the limitation in available precursors and the limitation in the types of films grown. The limitations of the CWCVD system are due to the facts that the sole heating element thereof has to provide the substrate temperature for growing the film but also the thermal energy for cracking the precursors either homogeneously or heterogeneously. Therefore, the CWCVD system is appropriate for growing materials, which have high thermal stability, and whose precursors are relatively easy to crack. On the contrary, if the cracking temperatures of the source precursors are too high and the grown film is highly thermally unstable, increasing the substrate temperature though can improve the cracking efficiency of source precursor, it often causes the decomposition/sublimation of the film itself, leading to the generation of large amounts of vacancies and defects, disfavoring the fabrication of high-quality materials.

The HWCVD system heats the entire reactor chamber to a given temperature, normally a relatively high temperature mostly for the purpose of cracking the source precursors. Such a system is particularly suitable for growing high thermal-stability film materials when their source precursors are hardly decomposed. One of the major prerequisite of using the HWCVD system to grow a film is that the selected precursors have to be nearly free from any detectable gas-phase side reactions at high temperatures. Since if it does occur, it will generate non-negligible amounts of nanometer- or micrometer-scale particles in the vapor phase, causing considerably the depletion of source precursors. Moreover, when these particles are incorporated into the solid, they certainly deteriorate seriously the film quality.

Differing from HWCVD, the TGCVD system has independent temperature controllability of the both upper and lower heating elements. The better way to take advantages of the TGCVD system is to conduct the film growth in a hot-top-cold-bottom operating mode. In this mode, the temperature of the upper heating element is higher than that of lower heating element. For most cases, the upper heating element is set at a temperature higher enough to crack the source precursors while the substrate is maintained at a temperature feasible for film growth and lower enough to avoid the volatile of the deposited film. However, such a CVD system is not always being applicable for multi-element film growths. This is because the more the source precursors used, the higher the chance of side reactions takes place. Once the side reactions arise either by single source itself or by the gas-phase interactions among several precursors, they will inevitably provoke chained reactions, and cause the losses of source precursors, disfavoring the growth of the film.

The MSCVD system is often used to grow film with an atomic layer growth scheme, wherein cation and anion precursors are fed respectively into different sub-reaction chambers. The rotating of susceptor heated by lower heating element allows the substrates cyclically exposing their growth surfaces to different individual source precursors. When the flow rates of source precursors, exposing time and substrate temperature are proper, self-limiting growth mechanism takes place, and the atomic layer epitaxial growth of film is realized. The apparent advantage of atomic layer epitaxy (ALE) by using MSCVD system is able to grow thin film with atomic thickness controllability, high uniform film thickness over a large area, and most importantly with a satisfactory film quality. Nevertheless, the ALE are thought to be applicable to limited materials, particularly to certain elemental or binary materials provided that the pyrolysis of their source precursors are undertaken simple processes without presence of any side reactions, and provided that the growth is via self-limiting growth mechanism wherein the growth stops spontaneously after a single monolayer coverage at one duty time. Nevertheless, the ALE growth of multi-element compound by MSCVD system is a tough job to be implemented. During the deposition, a plurality of cation-like and anion-like source precursors are fed respectively into their own sub-reaction chambers, and, we wish, conduct with lucks the respective ALE growth modes on the substrate. This sole substrate temperature has to fulfill the demands of the pyrolysis of all the source precursors into their proper active species and concurrently to satisfy the demands of the self-limiting growth conditions of individual binaries in multi-element compound, making such atomic layer growth truly difficult. For these reasons, it is generally accepted that the conventional MSCVD technology is not yet fully ready for the preparation of the atom layer growth of multi-element compounds, especially with high material quality.

### SUMMARY OF THE INVENTION

Addressing the problems and limitations of the conventional technologies, the present invention proposes a chemical vapor phase growth apparatus which comprises a lower heating element, wherein a plurality of carrier disks is disposed on a substrate holder, susceptor, heated by the lower heating element, and on each of the carrier disks has a plurality of substrates for film deposition; a plurality of partitions is disposed to divide the reaction chamber into a plurality of sub-reaction chambers. Each individual sub-reaction chamber comprises its own upper heating element, which including a plurality of independent-temperature controlled upper heating units arranged above the lower heating element; a gas inlet to provide carrier gases and at least one precursor flowing into this sub-reaction chamber.

During the film fabrication, the substrate holder (susceptor) is rotated to transport the substrates to different sub-reaction chambers for growing different films containing different elements. The following are some embodiments of the chemical vapor phase growth apparatus having a plurality of sub-reaction chambers of the present invention to make easily understood the objectives, technical contents, features and accomplishments of the present invention.

In one embodiment, the chemical vapor phase growth apparatus of the present invention comprising a plurality of sub-reaction chambers with upper heating elements set at different temperatures is in favor of solving the problem that different precursors respectively require different thermal cracking temperatures. During the film fabrication, the precursors respectively having different thermal cracking temperatures are fed into the arranged sub-reaction chambers. According to the requirements of thermal cracking temperatures of the precursors, the upper heating element is adjusted to a condition optimized for the thermal cracking of the precursors in the same sub-reaction chamber. Under this optimized condition, each precursor during the deposition is decomposed into active intermediate reactants or completely cracked into active atoms, whereby to prevent the impurities from the unbroken ligands into the films which functioning as the compensation centers or scattering centers in the film. Therefore, the chemical vapor phase growth apparatus of the present invention comprising a plurality of sub-reaction chambers can minimize to a great extent the impurities of the precursors from entering into the films, favoring the fabrication of high-quality film materials.

In another embodiment, the chemical vapor phase growth apparatus of the present invention comprising a plurality of sub-reaction chambers with upper heating elements set at different temperatures can grow high-quality films at low temperatures. In the present invention, the temperatures of a plurality of heating units of the upper heating element in each sub-reaction chamber can be controlled independently. Therefore, the precursors in their sub-reaction chamber can be thermally cracked respectively at their optimized thermal-cracking temperatures thereof, breaking into the active intermediate reactants, molecules or atoms necessitated by film fabrication. Accordingly, the substrate temperature heated by the lower heating element is needed to set a value only to meet the demand of energy required by surface chemical reactions to overcome the reaction barrier for film growth, not needed to raise further to fulfill the thermal cracking requirements of the hardly decomposed source precursors. Accordingly, the substrate temperature can be reduced noticeably as compared to that when grown by conventional CVD reactor. Thus, the chemical vapor phase growth apparatus of the present invention is distinct greatly from the conventional CWCVD system wherein the temperature of the substrate has to simultaneously meet the requirements of cracking a plurality of precursors and growing a film. Henceforth, the chemical vapor phase growth apparatus of the present invention comprising a plurality of sub-reaction chambers with upper heating elements is able to fabricate films at lower temperatures.

In yet another embodiment, the chemical vapor phase growth apparatus of the present invention comprising a plurality of sub-reaction chambers with upper heating elements set at different temperatures can diminish substantially or thoroughly the gas-phase side reactions. For example, if two or more precursors likely to generate side reactions among themselves are respectively fed into different sub-reaction chambers, whereby these reactants are exempted from mutual collisions before they reach the substrates. As a result, the side reactions that occur due to joint gas-interactions between precursors commonly seen in conventional CVD reactor can be eliminated greatly, especially under the high-temperature, high-pressure (>100 Torr) growth environment. Hence, the chemical vapor phase growth apparatus of the present invention comprising a plurality of sub-reaction chambers with upper heating elements not only can reduce presence of the side reactions to a great extent, but also can increase the usage efficiency of precursors and improve the quality of films.

In still another embodiment, the chemical vapor phase growth apparatus of the present invention comprising a plurality of sub-reaction chambers with upper heating elements is able to change the chemical reaction pathway of source precursors and hence the reaction routes for film deposition. The upper heating element of each sub-reaction chamber has a plurality of independent-temperature controlled upper heating units. During the film fabrication, while the operating temperature of the lower heating element (the substrate temperature) is determined, in each sub-reaction chamber the temperature of each of the upper heating units can be regulated to give a temperature variation on the surface of the upper heating element and thus generate 3D temperature profile in the sub-reaction chamber along both the axial and vertical directions. Since the temperature is an important factor to chemical reactions; therefore the changing of the 3D temperature distribution certainly can change the chemical reaction pathway of source precursors and hence the reaction routes for film deposition.

In a further embodiment, the chemical vapor phase growth apparatus of the present invention comprising a plurality of sub-reaction chambers with upper heating elements has a better chance to accomplish the ALD growth for a given film, particularly a multi-element compound. The ALD technology grows the film by cycling process. Each cycle is further divided into intervals of depositing different elements and intervals of cleaning/purging steps. In a given element interval, only one type of reactant is fed into a given sub-reaction chamber. In this interval, the reactant itself or its intermediate is attached to the substrate to form one atomic layer via self-limiting growth mechanism. That is to say after a complete cycle, one deposition layer is formed, containing a set of atom layers of the deposited compound material. However, the success of atomic layer deposition rests heavily on whether the growth parameters can fulfill the basic requirements of self-limiting growth mechanism, and the fabrication window thereof is usually not wide. The first prerequisite is whether the reactants can be converted into appropriate active intermediates suitable for ALE growth and the second prerequisite is whether the substrate temperature can satisfy all the demands of self-limiting growth mechanism required by each binary in multi-element compound. When the chemical vapor phase growth apparatus of the present invention being applied to undertake the ALD growth of a film, since each sub-reaction chamber is only allowed one precursor to feed into and its upper heating element is thermostated to produce its own temperature profile, thereby each precursor can crack in accord to its own cracking demand into the appropriate intermediate products, leaving only the second prerequisite to be fulfilled for ALE growth. Thus, the present invention comprising a plurality of sub-reaction chambers with upper heating elements has more opportunities to realize ALD of multi-element film materials with high quality.

### BRIEF DESCRIPTION OF THE DRAWINGS

The present invention is illustrated by the description given herein below, and the accompanying drawings which are given by way of illustration only and thus are not limitative of present invention, and wherein;

FIG. 1 illustrates a sectional view schematically showing a chemical vapor phase growth apparatus according to one embodiment of the present invention;

FIG. 2A illustrates a partial cross-section showing a chemical vapor phase growth apparatus according to one embodiment of the present invention;

FIG. 2B illustrates a partial cross-section showing a chemical vapor phase growth apparatus according to other embodiment of the present invention;

FIG. 2C illustrates a partial cross-section showing a chemical vapor phase growth apparatus according to another embodiment of the present invention;

FIG. 3 illustrates a sectional view schematically showing a chemical vapor phase growth apparatus according to another embodiment of the present invention; and

FIG. 4 illustrates a partial cross-section showing a chemical vapor phase growth apparatus according to another embodiment of the present invention.

### DESCRIPTION OF THE PREFERRED EMBODIMENTS

The following embodiments are used to further demonstrate the characteristics of the chemical vapor phase growth apparatus of the present invention. However, the films mentioned in the embodiments are only for conveniently explaining the present invention but not for limiting the scope of the present invention.

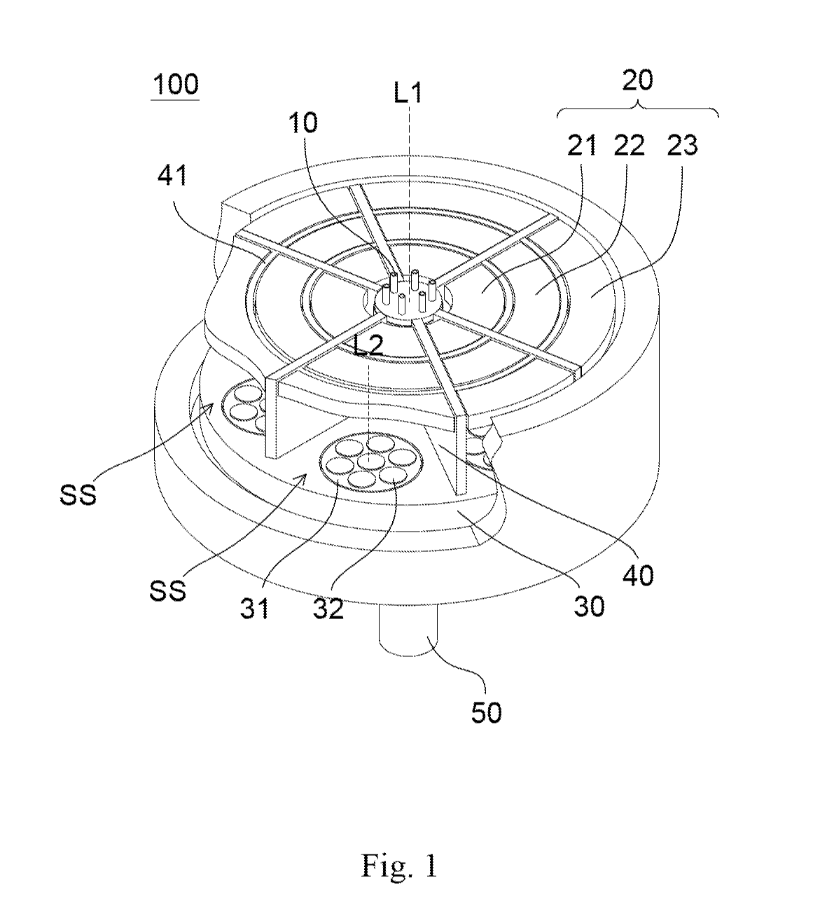

Referring to FIG. 1, the chemical vapor phase growth apparatus 100 of the present invention comprises of a lower heating element 30, wherein a plurality of carrier disks 31 is arranged on the lower heating element 30, and wherein each carrier disk 31 carries a plurality of substrates 32 where films are deposited; a plurality of partitions 40 is arranged at positions above the lower heating element to divide the reaction chamber into a plurality of sub-reaction chambers SS. Each sub-reaction chamber SS further comprises an upper heating element 20 made up of a plurality of thermostated upper heating units 21, 22 and 23 separated by insulators 41. The upper heating element 20 is arranged above the lower heating element 30 and separated vertically by a gap to form a hot-temperature reaction zone RZ. The chemical vapor phase growth apparatus also comprises a gas inlet 10 to allow at least one precursor flowing into the individual sub-reaction chamber SS.

The lower heating element 30 can rotate with respect to the central axis L1 thereof; each carrier disk 31 can rotate with respect to the central axis L2 thereof. While the lower heating element 30 undertakes a clockwise or counterclockwise revolution about the central axis L1, the carrier disks 31 carrying substrates 32 thereon are moved to different sub-reaction chambers SS. While the carrier disk 31 undertakes a spin, film is uniformly deposited on the substrates 32.

In this embodiment, the upper heating units in the upper heating element 20 have fan shapes and the lower heating element 30 has a round shape. The gap between the upper heating element 20 and the lower heating element 30 can be adjusted to fulfill the optimum growth conditions. The angle between two adjacent partitions 40 can be adjusted to meet the growth requirements, preferably in the range from 10 to 180 degrees.

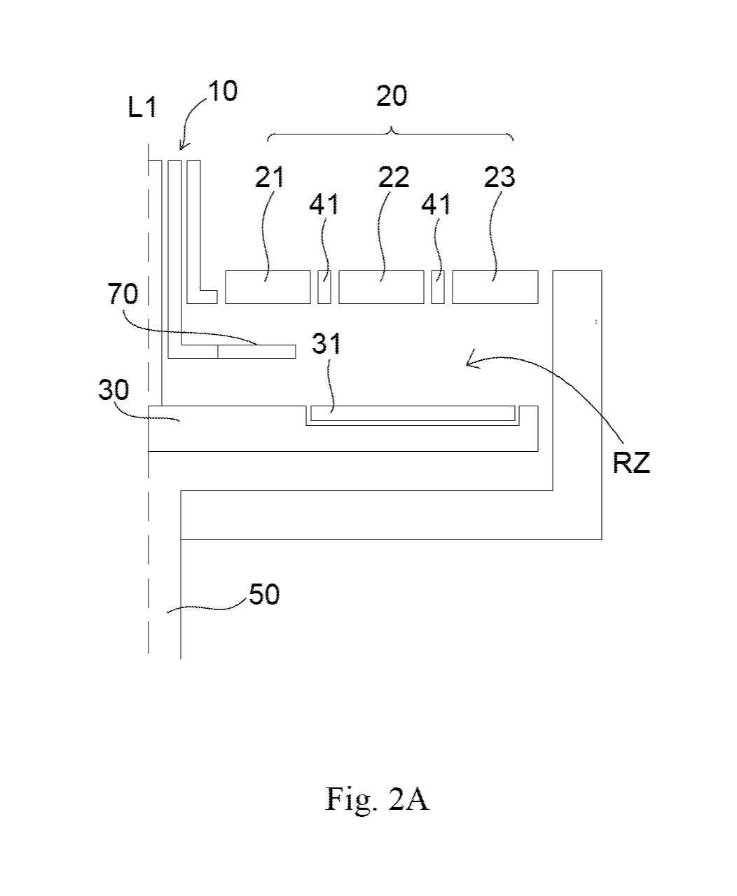

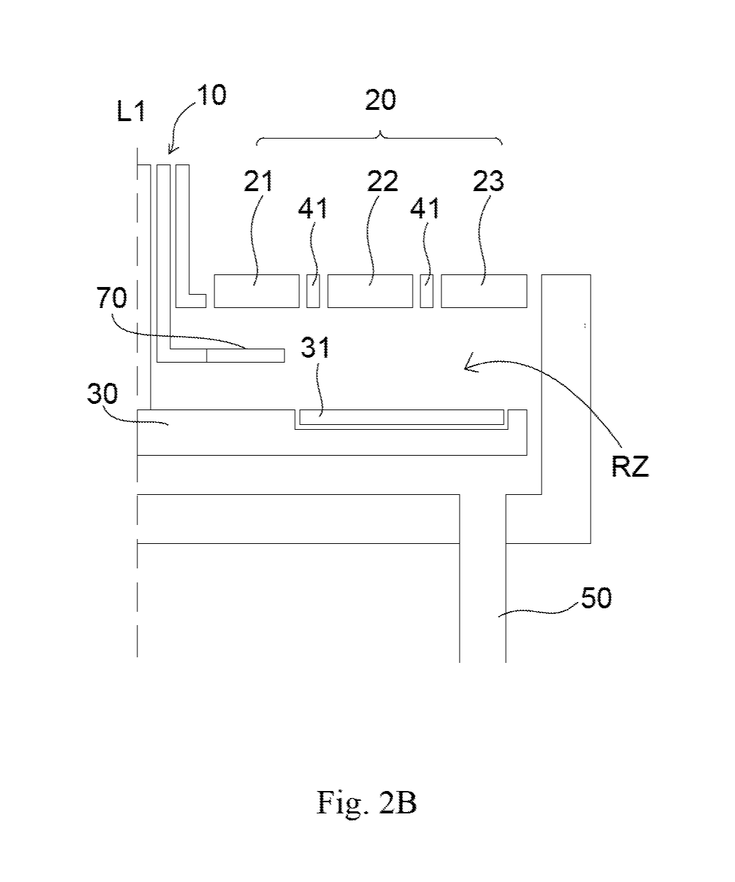

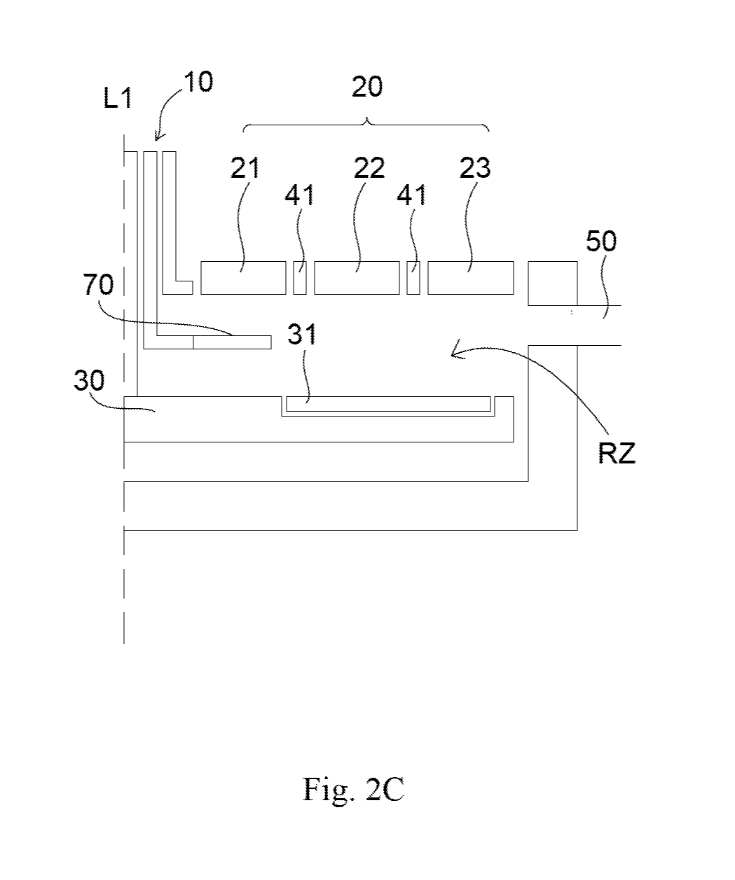

Referring to FIG. 2A, in this embodiment, in one deposition run, the lower heating element 30 is set at a first temperature, and the upper heating element 20, including upper heating units 21, 22 and 23 in a given sub-reaction chamber, are all set at the same second temperature, whereby the hot-temperature reaction zone RZ of this sub-reaction chamber has a nearly the same temperature gradient in the vertical direction along the radial direction. In another deposition run the lower heating element 30 provides a first temperature; the upper heating units 21, 22 and 23 of the upper heating element 20 respectively in a given sub-reaction chamber provide a second temperature, a third temperature and a fourth temperature, whereby the hot-temperature reaction zone RZ in this sub-reaction chamber SS owns its specified 3D temperature variation along the radial direction and the vertical direction.

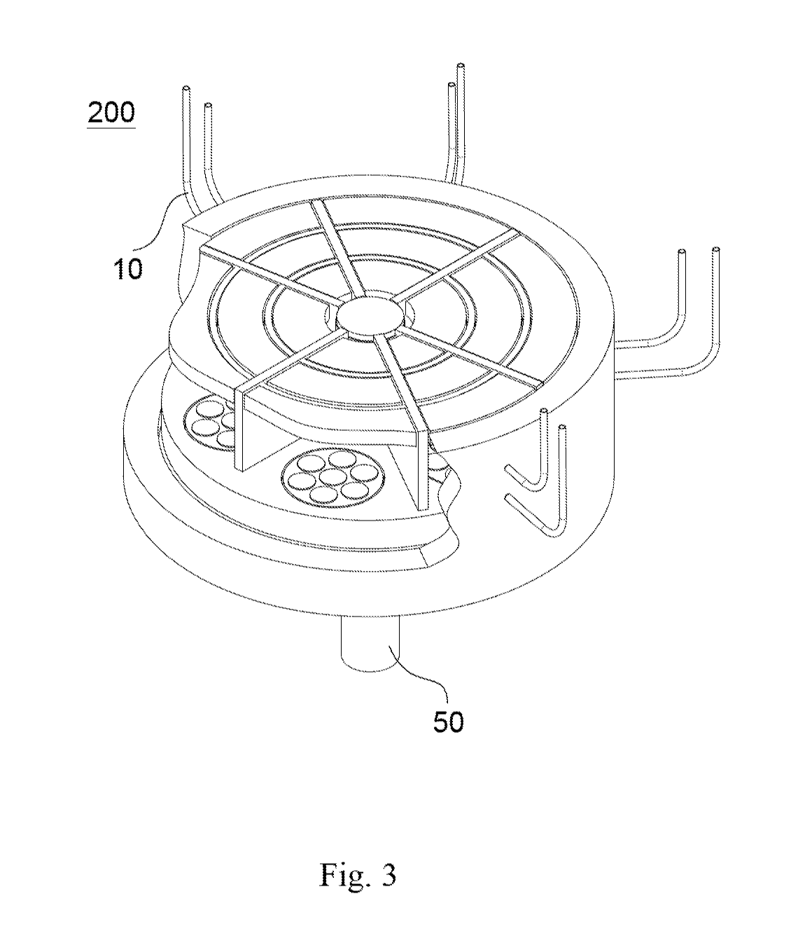

The chemical vapor phase growth apparatus 100 of the present invention comprises a gas inlet 10 and a gas outlet 50. The gas outlet 50 and the gas inlet 10 can be arranged in different positions according to requirement. In one embodiment as shown in FIG. 2A, the gas inlet 10 is arranged in the center of the chemical vapor phase growth apparatus 100, and the gas outlet 50 is arranged in the center of the chemical vapor phase growth apparatus 100, by which exhaust gas from the periphery of growth apparatus is collected. Furthermore, the gas outlet 50 for exhaust gas can be also arranged in the peripheries of the chemical vapor phase growth apparatuses, as shown in FIGS. 2B and 2C. Referring to FIG. 3, in a still another embodiment the gas inlet 10 is arranged in the periphery of the chemical vapor phase growth apparatus 200, and the gas outlet 50 is arranged in the center of the chemical vapor phase growth apparatus 200. In a yet still another embodiment, the gas inlet 10 includes a device that is capable of making the input reactants flowing smoothly on the epitaxial area above the substrate without lateral mixing

In a further embodiment, each of the upper heating element and the lower heating element includes at least one contact heating device and/or at least one non-contact heating device. The contact heating device may be a filament heating device or a ceramic heating device. The non-contact heating device may be a high-frequency electromagnetic induction heating device, an ultraviolet heating device, a visible-light tube lamp, or an infrared tube lamp.

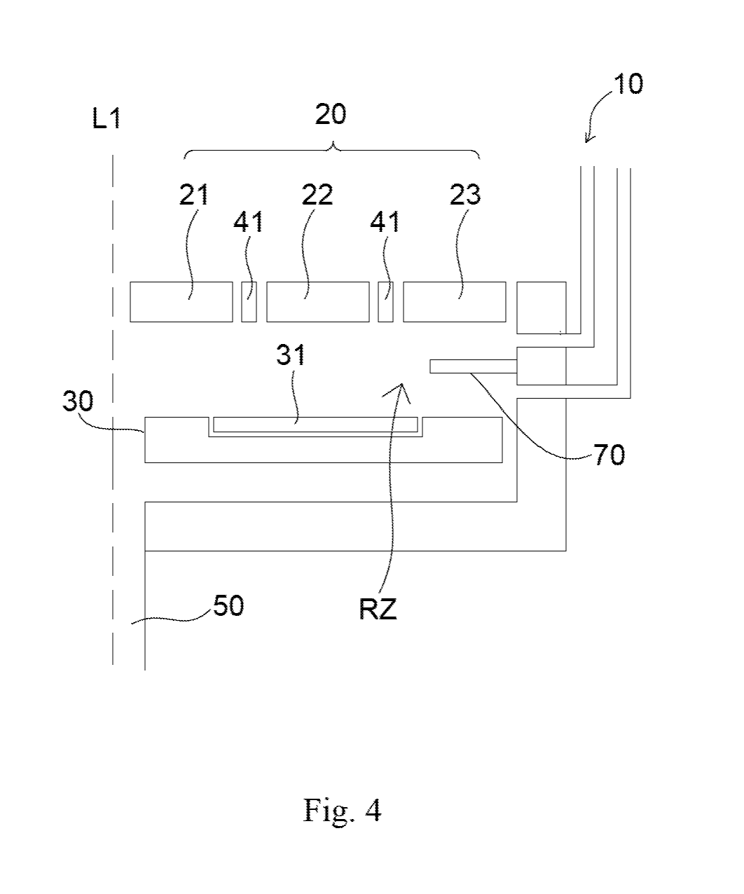

In a yet further embodiment, the chemical vapor phase growth apparatus of the present invention further comprises a cooling device, which may be arranged in/near the upper heating element 20, the lower heating element 30, or the partitions 40 disposed between the adjacent sub-reaction chambers or the insulators 41 between the adjacent heating units 21, 22, and 23 as mentioned above. In a still further embodiment, the plurality of partitions 40 and insulators 41 is a hollow structure, and coolant fluid flows inside the hollow structure to modify the temperature. In a still further embodiment, the plurality of partitions 40 and insulators 41 is a solid structure. In a still further embodiment, the plurality of partitions 40 disposed between the adjacent sub-reaction chambers is of a rectangular shape, a right-angle trapezoidal shape, or a right-angle trapezoidal shape wherein the slant side is replaced by a curved shape, wherein the dimensions of partitions can be adjusted to meet the growth requirements. In a still further embodiment, the chemical vapor phase growth apparatus of the present invention further comprises gas separators 70, as shown in FIG. 2A, FIG. 2b, FIG. 2C and FIG. 4, in the portions of individual sub-reaction chambers adjacent to gas inlet 10 to separate the flow paths of source precursors and carrier gases there, wherein parts of separators can overlap with parts of either upper heating element or lower heating element, as viewed from the top of apparatus.

The bellows give examples to describe how to make films using the chemical vapor phase growth apparatus of the present invention. In one embodiment, the present invention is exemplified by using the apparatus to fabricate a SiGe heterojunction bipolar transistor (SiGe HBT. For 200 GHz SiGe HBT, its base normally has about 25% Ge and 75% Si and a thickness of 25 nm. The emitter and collector of SiGe HBT are normally made of Si. There is a 4% difference between the lattice constant of Ge (5.65 Å) and the lattice constant of Si (5.43 Å). In order to maintain the quality of film, the thickness of the SiGe base is required to be smaller than the threshold thickness in order to avoid the coarsening of film surface and the generation of intrinsic structure defects. The threshold thickness correlates closely with the film growth temperature. The threshold thickness of Si_{0.75}Ge_{0.25}/Si is 10 nm at 900° C. and 30 nm at 600° C. For this reason, it has no choice but to grow the Si_{0.75}Ge_{0.25} film of SiGe HBT using conventional cold-wall CVD at ˜600° C. so that the 2D layer growth mode can be maintained. Nevertheless, the precursors GeH₄ and SiH₄ have higher cracking temperatures. Such a substrate temperature (600° C.) is far lower than the onset cracking temperatures of GeH₄ and SiH₄ (both of them are about 790° C.). Obviously, by means of cold wall CVD the 600° C. substrate temperature cannot pyrolyze effectively the source precursors here. Incomplete cracking of precursors certainly will cause the generation of massive impurities and structural defects (such as vacancies, dislocations and voids), which will deteriorate the electrical and optical properties of the film and impair the device performance.

On the contrary, when the chemical vapor phase growth apparatus of the present invention is used to fabricate the base of the above SiGe HBT, while the substrate temperature provided by the lower heating element 30 is set at 600° C. or lower to meet the threshold thickness demand, the temperatures of upper heating element 20 in the sub-reaction chambers SS can be set at much higher values in order to crack efficiently the GeH₄ and SiH₄ precursors. For instance, if GeH₄ and SiH₄ are respectively fed into their individual sub-reaction chambers SS, the upper heating element 20 of the SiH₄ sub-reaction chamber can be set at 1145° C., and the upper heating element 20 of the GeH₄ sub-reaction chamber can be set at 850° C. Thereby, these precursors can be cracked satisfactorily and converted into the active species, such as SiHₓ and GeHₓ (x=0-2), required for the film fabrication. Since the substrate temperature is waived the obligation to provide thermal energy for cracking source precursors, its temperature can be further lowered. Therefore, it can be inferred that the chemical vapor phase growth apparatus of the present invention is capable of growing films at low temperatures, ascribing to the cracking of source precursors being done separately by the upper heating elements 20 in each sub-reactor chambers.

In another embodiment, the present invention is exemplified by using the apparatus to grow AlGaN film. The AlGaN film usually functions as a high-energy gap layer or a barrier layer in the GaN-based optoelectronic and electronic devices. The precursors, usually used to grow AlGaN films, are Ga(CH₃)₃, Al(CH₃)₃, and NH₃. For conventional AlGaN CVD growth at a growth pressure of 200 mbar, the Al(CH₃)₃ and NH₃ are simultaneously fed into the exclusive reaction chamber. Being a Lewis acid-base pair, Al(CH₃)₃ and NH₃ once mixed together are soon to polymerize into an adduct Al(CH₃)₃:NH₃ in a vapor phase. These adducts are cracked into Al(CH₃)₂:NH₂, diffusing toward the substrate surface and then conducting surface chemical reaction steps to form the AlN component in the AlGaN film. Beside film deposition process, polymerization reaction paths also take places from Al(CH₃)₂:NH₂ to form [DMAl—NH₂]₂ and [DMAl—NH₂]₃ nanoparticles. Such side reactions would lead to the depletion of source precursors, increase uncertainty of fabrication processes, and degrade film quality, especially under a high-temperature, high-pressure growth ambient.

Unlike the conventional CVD growth, the chemical vapor phase growth apparatus of the present invention can respectively feeds Al(CH₃)₃ and NH₃ into their respective sub-reaction chambers in the AlGaN film growth, lest they collide together in the gas phase prior to the deposition, and hence lest the side reactions occur. Therefore, the present invention can effectively reduce, the side reactions in film deposition and increase the usage efficiency of precursors.

Referring to FIG. 2A, in another embodiment the upper heating units (21, 22, 23) of the upper heating element 20 is used in a way by setting at different temperatures and hence generating 3D temperature profile in each individual sub-reaction chamber in the chemical vapor phase growth apparatus of the present invention, which is exemplified also by the growth of AlGaN film, assuming the TMAl and NH₃ are fed into the same sub-reaction chamber SS but separate by separator 70 in the front portion of the sub-reaction chamber, wherein the TMAl flows in the upper gas channel and NH₃ flow the lower gas channel. During the deposition, the upper heating unit 21 of the TMAl sub-reaction chamber SS, which is near the gas inlet, can be tuned at a temperature ˜350° C., while keep all the other upper heating units 22 and 23 at high temperatures. Provided that the separator 70 and heating unit 21 are overlapped over a large portion of area, viewed from top of chamber, the input TMAl here tends to crack itself into DMAl or MMAl in the front portion of the sub-reaction chamber due to the use of the separator, and blocks the formation of TMAl:NH₃ adduct at the rest portions of the chamber, since the TMAl is no more existed in this region where the Al- and N-relevant species are mixed. That avoids the generation of side reactions of [DMAl—NH₂]₂ and [DMAl—NH₂]₃ nanoparticles. Therefore, 3D temperature profiles can be generated in individual sub-reaction chambers in the chemical vapor phase growth apparatus of the present invention, which often can alter the reaction routes in the gas phase and sometimes can benefit to the film deposition, such as preventing the formation of side reactions.

The conformity and uniformity of a film becomes more and more important for 3D device growth at nanometric scale. To meet the needs, the industry often uses the atomic layer deposition (ALD) technology to fabricate these films. For example, for a 16 nm SiGe fin field effect transistor (FinFET) the Al₂O₃ insulator is required to have material qualities of low leakage current and high resistance. For conventional ALD growth, the growth of Al₂O₃ film is normally conducted at a substrate temperature about 300° C. to prevent the thermal effects from damaging the electric properties of the device structure grown earlier. However, this temperature, 300° C., is lower than the onset cracking temperature of the first ligand of the precursor Al(CH₃)₃, 350° C., and far below the onset cracking temperature of the last ligand, 530° C. In other words, at a substrate temperature of 300° C., most of the Al(CH₃)₃ precursors have not yet cracked in the gas phase. Impurities (such as C atoms and H atoms) carried by these intermediate reactants are inevitably entering into the solid, resulting in a heavy C doping, about 0.5%, in the ALD grown Al₂O₃ film. Such a high carbon concentration responses for the high leakage current in the Al₂O₃ insulating layer, which degrades considerably the device performance.

The chemical vapor phase growth apparatus of the present invention can satisfy the requirement in using ALD technology to grow higher quality Al₂O₃ film via respectively feeding the precursors Al(CH₃)₃, H₂O, carried by carrier gas into different sub-reaction chambers. By setting the upper heating elements 20 at respective adequate high temperatures and/or temperature profiles, the individual Al(CH₃)₃ and H₂O reactants can be cracked sufficiently in their individual sub-reaction chambers. For instance, while maintaining the substrate temperature at a given temperature, say 300° C., the upper heating element 20 of the Al(CH₃)₃ sub-reaction chamber can be heated to >530° C., such as 650° C., at which Al(CH₃)₃ will crack into active Al atoms before reaching the substrate surface. This could not only reduce the steric hindrance effect during the deposition, but also favor the “self-limiting growth mechanism” during the ALD deposition. Because of nearly completely pyrolysis of the Al(CH₃)₃ precursors, the present invention can therefore effectively prevent impurities (such as C atoms) from entering into the film and thus improve the film quality of Al₂O₃ layer.

In conclusion, the chemical vapor phase growth apparatus of the present invention comprises a plurality of sub-reaction chambers with upper heating elements, wherein the temperature profiles of the individual sub-reaction chambers can be independently controlled to allow the precursors having different cracking temperatures to crack at their adequate temperature environments. Additionally, the side reactions that occur in the film growth by conventional CVD apparatus particular at high-pressure and high-temperature ambient can also be minimized to a great extent by means of separating the source precursors flowing into different sub-reaction chambers when using our CVD apparatus. Furthermore, since each of sub-reaction chambers of the chemical vapor phase growth apparatus of the present invention has a plurality of upper heating units whose temperatures can be independently regulated, whereby a 3D temperature profile is resulted along the radial direction and the vertical directions, wherefore not only the cracking efficiency of the precursors can be increased, but also the reaction routes can be changed, which in most cases can favor the high-quality film growth.

What is claimed is:

1. A chemical vapor phase growth apparatus comprising of:
a lower heating element, wherein a plurality of carrier disks is arranged on the lower heating element, and wherein each carrier disk carries a plurality of substrates where films are deposited;
a plurality of partitions disposed at positions above the lower heating element to divide the growth apparatus into a plurality of sub-reaction chambers;
an upper heating element in each sub-reaction chamber, arranged above the lower heating element and separated vertically to form a reaction zone, wherein the upper heating element has a plurality of thermostated upper heating units;
a gas inlet installed in each sub-reaction chamber to allow at least one precursor to enter the sub-reaction chamber; and
a gas outlet installed on the growth apparatus to exhaust the gases.

2. The chemical vapor phase growth apparatus according to claim 1, wherein the lower heating element rotates with respect to a central axis thereof, and the plurality of carrier disks rotate with respect to their own central axes thereof.

3. The chemical vapor phase growth apparatus according to claim 1, wherein the lower heating element is round-shaped and the upper heating element in each sub-reaction chamber is fan-shaped.

4. The chemical vapor phase growth apparatus according to claim 3, wherein the angle between adjacent partitions ranges from 10 to 180 degrees.

5. The chemical vapor phase growth apparatus according to claim 1, wherein the gas inlet of the sub-reaction chamber is arranged in the center of the chemical vapor phase growth apparatus, and the gas outlet is arranged in the periphery of the chemical vapor phase growth apparatus.

6. The chemical vapor phase growth apparatus according to claim 1, wherein the gas inlet of the sub-reaction chamber is arranged in the periphery of the chemical vapor phase growth apparatus, and the gas outlet is arranged in the center of the chemical vapor phase growth apparatus.

7. The chemical vapor phase growth apparatus according to claims 1, wherein portion of each sub-reaction chamber adjacent to the gas inlet further comprises of gas separators to separate the flows of source precursors and/or carrier gas.

8. The chemical vapor phase growth apparatus according to claim 1, wherein the upper heating elements and the lower heating element include a plurality of contact type heating devices or a plurality of non-contact type heating devices.

9. The chemical vapor phase growth apparatus according to claim 8, wherein the contact type heating devices include filament-heating devices or ceramic-heating devices.

10. The chemical vapor phase growth apparatus according to claim 8, wherein the non-contact type heating devices include high-frequency electromagnetic induction heating devices, ultraviolet-heating devices, visible-light tube lamps, or infrared tube lamps.

11. The chemical vapor phase growth apparatus according to claim 1, wherein each of the upper heating element and the lower heating element include at least one cooling device.

12. The chemical vapor phase growth apparatus according to claim 1, wherein the partition is either a solid structure or a hollowed structure.

13. The chemical vapor phase growth apparatus according to claim 12, wherein the partition is a hollowed structure allowing coolant fluid to flow in.

14. The chemical vapor phase growth apparatus according to claim 1, wherein the partition is a rectangular shape, a right-angle trapezoidal shape, or a right-angle trapezoidal shape wherein the slant side is replaced by a curved shape.
